(19) United States
(12) Patent Application Publication
(10) Pub. No.: US 2012/0244282 A1
(43) Pub. Date: Sep. 27, 2012

(54) VAPOR DEPOSITION SOURCE

(75) Inventors: Ralf T. Faber, Lexington, MA (US); Ronald A. Crocker, Hanover, MA (US); Keqi Zhang, Wayland, MA (US); Joseph Patrinostro, Centerville, MA (US); James S. Snyder, Suffield, MA (US)

(73) Assignee: VACUUM PROCESS TECHNOLOGY LLC, Plymouth, MA (US)

(21) Appl. No.: 13/427,323

(22) Filed: Mar. 22, 2012

Related U.S. Application Data
(60) Provisional application No. 61/467,804, filed on Mar. 25, 2011.

(51) Int. Cl. C23C 16/448

(52) U.S. Cl. 427/255.5; 118/726

(57) ABSTRACT

A vapor deposition source for vaporizing a material has a body forming an interior chamber, at least one crucible in the interior chamber, and a divider that divides the interior chamber into a transport channel and a distribution channel. To deposit vapor on an underlying substrate, the deposition source also has a plurality of exit orifices formed in the body adjacent to the distribution channel. The divider has a set of divider apertures between the transport channel and the distribution channel. This divider aperture is positioned generally symmetrically within the interior chamber.

### PRIORITY

This patent application claims priority from provisional U.S. patent application No. 61/467, 804 filed Mar. 25, 2011, entitled, “VAPOR DEPOSITION SOURCE,” and naming Ralf T. Faber, Ronald A. Crocker, Keqi Zhang, Joseph Patrinostro, and James S. Snyder as inventors, the disclosure of which is incorporated herein, in its entirety, by reference.

### FIELD OF THE INVENTION

The invention generally relates to deposition sources and, more particularly, the invention relates to controlling vapor deposition on a substrate.

### BACKGROUND OF THE INVENTION

Many devices and products have thin films of material that were formed using precision coating equipment. For example, many types of photovoltaic cells use precision vapor deposition equipment to deposit a very thin metal coating onto a flat substrate having a relative large surface area. In many cases, the uniformity of the coating thickness substantially impacts product performance—whether it is a photovoltaic cell or other device. Accordingly, those in the art have developed a wide variety of techniques and systems in an effort to effectively control the thin film deposition process.

### SUMMARY OF THE INVENTION

In accordance with one embodiment of the invention, a vapor deposition source for vaporizing a material has a body forming an interior chamber having at least two ends, first and second crucibles in the interior chamber, and a divider that divides the interior chamber into a transport channel and a distribution channel. The first crucible is positioned proximate to the first chamber end, while the second crucible is positioned proximate to the second chamber end. The source also has a plurality of exit orifices formed in the body adjacent to the distribution channel. The divider has a set of divider apertures between the transport channel and the distribution channel. That set of divider apertures is generally symmetrically positioned relative to the distribution channel within the interior chamber.

The set of divider apertures may include no more than one divider aperture, or a plurality of divider apertures. Alternatively or in addition, the plurality of exit orifices formed in the body may be between the first and second crucibles. To better control vapor flow and mitigate spitting, the transport channel volume may be less than the distribution channel volume. Additionally, in some embodiments, the transport channel has a length that is at least 3 times greater than its height.

The relationship between the two channels also improves performance. For example, the transport channel may be vertically aligned with the distribution channel. Moreover, the (at least one) crucible may include first and second crucibles that are generally symmetrically positioned relative to the set of divider apertures.

In accordance with another embodiment of the invention, a vapor deposition source for vaporizing a material has a body forming an interior chamber, at least one crucible in the interior chamber for supporting and providing material vapor, and a plurality of exit orifices formed in the body to expose the interior chamber to the exterior of the body. The body has a generally elongated shape with a pair of end regions, while the plurality of exit orifices are at least positioned generally along the length between the end regions. The plurality of exit orifices have different geometries. Specifically, the plurality of exit orifices include an edge orifice and interior orifice. The edge orifice is positioned between one of the end regions and the interior orifice, and has a geometry that permits substantially the same material flux through it as the material flux through the interior orifice when the pressure proximate to the edge orifice is lower than the pressure proximate to the interior orifice.

Accordingly, this geometry should improve the deposition pattern near the edge of the underlying substrate being coated. Among other ways to form this geometry, the edge orifice may have a greater cross-sectional area than the interior orifice.

The deposition source also may have a removable member removably connected with the body. This removable member may include at least one of the plurality of exit orifices. For example, the removable member may include an array (e.g., a one or two dimensional array) of exit orifices.

The exit orifices may be removable. Specifically, the deposition source may have a plurality of removable members. Each removable member has a plurality of exit orifices, and at least two of the removable members may have dissimilar exit orifices from one another. To that end, the body may include an opening and a removable member removably secured within the opening. As noted, the removable member includes at least one of the plurality of exit orifices.

In accordance with other embodiments of the invention, a vapor deposition source for vaporizing a material has a body forming an interior chamber, at least one crucible in the interior chamber for vaporizing material, and a plurality of exit orifices formed in the body to expose the interior chamber to the exterior of the body. The body having a cylindrically shaped portion with a circumference of greater than about 180 degrees.

More specifically, the body has a cross-sectional shape that is either circular or elliptical. The deposition source also may include a plurality of suspending members coupled with the body. The plurality suspending members have connections to connect with a securing apparatus for suspending the source.

The exit orifices interrupt the outside surface of the body. In addition, the body includes a high temperature material layer, and a one-piece insulation layer radially outwardly of the high temperature material. For example, the high temperature material layer may include fine grain high density graphite. Illustrative embodiments of the body have no seams or edges along the exterior body circumference.

In accordance with still other embodiments of the invention, a vapor deposition source for vaporizing a material has an elongated body forming an interior chamber, and at least one crucible in the interior chamber for vaporizing material. The interior chamber forms a distribution channel having a channel volume. The deposition source thus also has a plurality of exit orifices formed in the body to expose the distribution channel to the exterior of the body. In a manner similar to the distribution channel, each of the plurality of exit orifices has an orifice volume. In illustrative embodiments, the channel volume is at least five times the sum of the orifice volumes of all of the exit orifices.

The distribution channel preferably shields a majority of the exit orifices from each of the at least one crucibles. For example, the interior chamber may form transport channel for directing vapor into the distribution channel. The transport channel is elongated and sized to substantially eliminate material spitting. In addition, or in the alternative, the transport channel, which is fluidly connected to the distribution channel at a channel interface, may be spaced from the exit orifices and have a length and a height that substantially eliminates material spitting. For example, the transport channel may have a length that is at least three times greater than its average height.

When in use, the distribution channel illustratively has a substantially constant vapor pressure distribution. In a similar manner, also when in use, the pressure distribution across the exit orifices illustratively is substantially constant.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a perspective view of a vapor deposition source configured in accordance with illustrative embodiments of the invention.

FIG. 2 schematically shows a perspective view of the vapor deposition source of FIG. 1 with the portion of its outside insulation removed.

FIG. 3 schematically shows a perspective view of insulation for the body of the vapor source shown in FIG. 1.

FIG. 4 schematically shows a bottom view of the vapor deposition source of FIG. 1.

FIG. 5 schematically shows a perspective view of the vapor deposition source of FIG. 1 with its interior and exterior walls removed, more clearly showing the heating system and divider.

FIG. 6 schematically shows a perspective, longitudinal cross-sectional view of the vapor deposition source of FIG. 1.

FIG. 7 schematically shows a longitudinal cross-sectional view of a portion of the vapor deposition source of FIG. 1.

FIG. 8 schematically shows an exploded view of one end of the vapor deposition source of FIG. 1.

FIG. 9 schematically shows a nozzle insert having a plurality of openings. This insert may be removably coupled with the vapor deposition source of FIG. 1.

### DESCRIPTION OF ILLUSTRATIVE EMBODIMENTS

In illustrative embodiments, a vapor deposition source is sized and configured to efficiently and controllably deposit a substantially uniform layer of material onto a substrate. To that end, among other things, the vapor deposition source may have a substantially rounded design with an internal distribution channel having a symmetrically located opening for receiving vapor. Specially configured nozzles emit the vapor in a predefined manner to optimize performance. Finely tuned pressures within the source further ensure carefully controlled vapor deposition onto the substrate. Details of illustrative embodiments are discussed below.

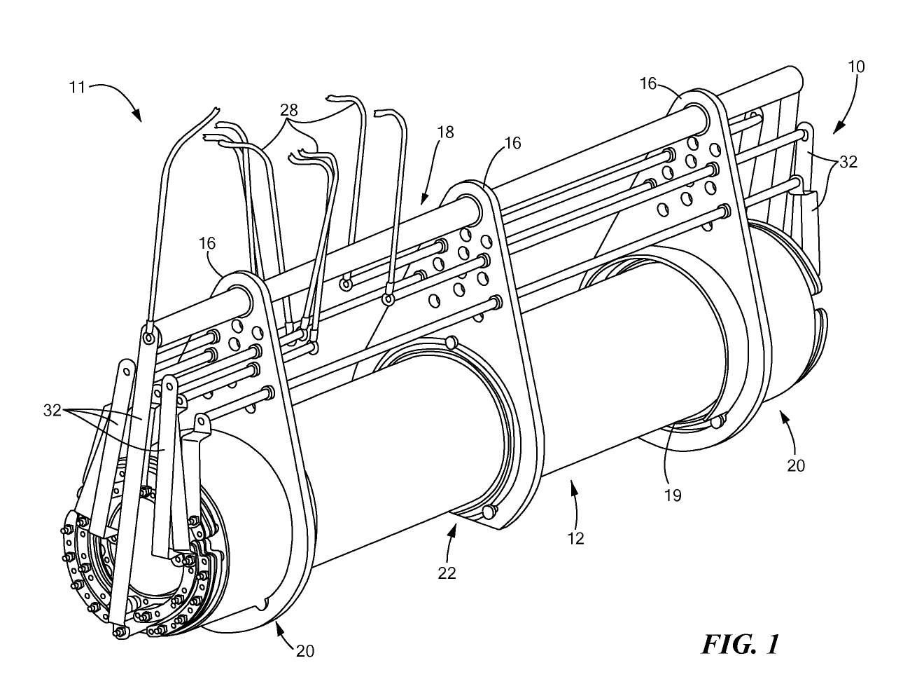

FIG. 1 schematically shows a perspective view of a vapor deposition source (hereinafter “deposition source 10”) configured in accordance with illustrative embodiments of the invention. Specifically, as known by those skilled in the art, the deposition source 10 deposits a thin layer of material, such as copper, indium, or zinc, onto an underlying substrate. Among other ways, the substrate may receive the vapor as it passes underneath the deposition source 10 on a conveyor belt. As noted above, the coated substrate ultimately may form a photovoltaic cell. Of course, discussion of a photovoltaic cell is but one of many potential devices produced in part by the deposition source 10. Accordingly, discussion of a photovoltaic cell is for exemplary purposes only.

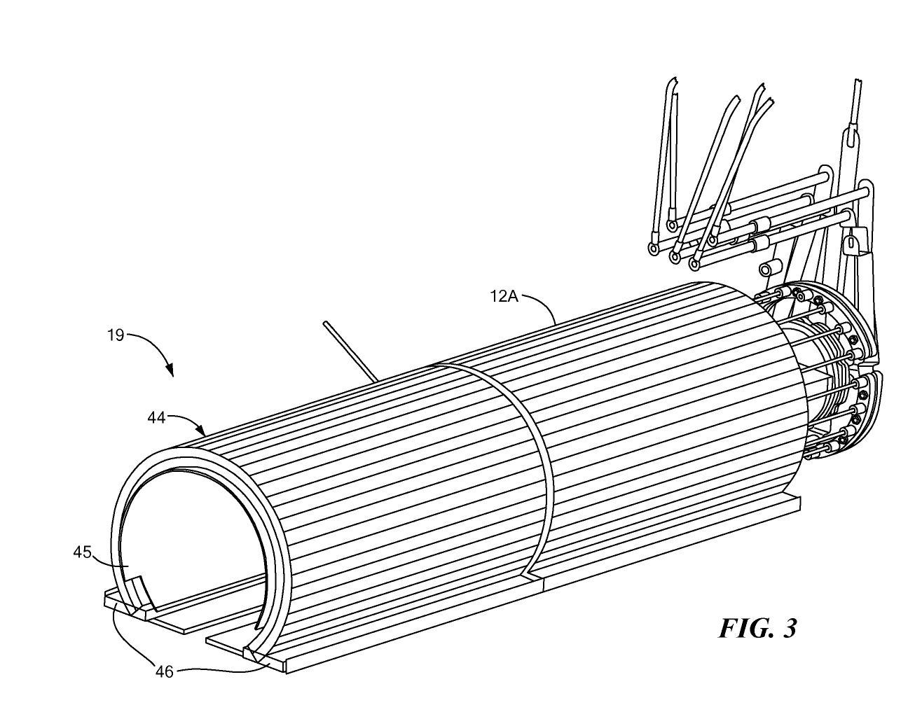

The deposition source 10 of this embodiment has a substantially longitudinally-symmetric shaped body 12 for more evenly distributing material vapor throughout its interior (discussed below). To that end, in illustrative embodiments, the body 12 has an elongated, substantially cylindrically shaped portion that effectively reduces its overall profile and footprint. Accordingly, that portion 12A (FIG. 3) of the body 12 has a cross-sectional shape that is generally circular or elliptical, where the longitudinal axis of the body 12 serves as the center of the circles/ellipses. The cylindrical portion 12A, as well as the rest of the body 12, with its longitudinally-symmetric shape, thus is capable of division, into similar halves, by a plane oriented parallel to a middle plate 16 (orthogonal to the longitudinal axis) at its longitudinal center. The general shape of these two body halves may be substantial mirror images of each other, or the substantially identical halves. The body 12 is not necessarily symmetric when divided by planes parallel with the longitudinal axis. The body 12 may have this shape either internally (i.e., within its interior), externally, or both.

It should be noted, however, that the body 12 may have certain non-dominant features, such as exit orifices 14 (discussed below) or protrusions, that interrupt the cross-sectional circular or elliptical body shape of the cylindrical body portion 12A. Such interruptions nevertheless should not be considered to change the (principal) shape of certain embodiments the body 12 from being cylindrical. This should be contrasted with a body 12 having a significant elongated, flat/planar region along its length (e.g., see FIG. 3). For example, a flat portion taking up 20 degrees of the circumference of the cylinder along its length may be considered to cause the body 12 to have a partially-cylindrical shape—not a substantially cylindrical shape. As another example, a flat portion taking up to even 135 degrees of the circumference of the cylinder still may be considered to have a partially-cylindrical shape. In either of these latter two cases, the cylindrical portion 12A makes up the principal portion of the body. For example, the cylindrical portion 12A may have a circumference of more than about 180 degrees, 200 degrees, 245 degrees, 270 degrees, 300 degrees, 330 degrees, etc. . . .

In alternative embodiments, the body 12 has a different, non-rectangular shape. For example, the body 12 may have a non-elliptical shape but, like the elliptical embodiments, has no edges or seams (e.g., a clover-like shape). Other embodiments, however, may have a rectangularly shaped body 12 and thus, have edges and/or seams.

A plurality of suspension brackets 16 or other means suspend the deposition source 10 within the interior of a vacuum chamber (shown only schematically by FIG. 1 and identified by reference number 11). As noted above, a substrate to be coated passes underneath (or elsewhere, such as above, depending on the source configuration) the deposition source 10 to receive the vapor layer. To those ends, the deposition source 10 of FIG. 1 has three suspension brackets 16 and a crossbar 18 extending through the brackets 16 for supporting the source 10. The suspension brackets 16 and crossbar 18 may couple with some connector in the vacuum chamber 11 to suspend the deposition source 10. In addition, the three support brackets 16 also provide structure for electrical interconnects between different portions of the deposition source 10.

The body 12 has three primary regions; namely, two end regions 20 for containing the material to be vaporized, and an elongated central distribution region 22 for directing the vapor from its interior and toward the substrate.

These regions 20 and 22 preferably are all within the chamber 11. As noted above, in illustrative embodiments, the body 12 symmetrically forms a mirror image about its center—mirror image end regions 20 and respective adjacent portion of the distribution region 22.

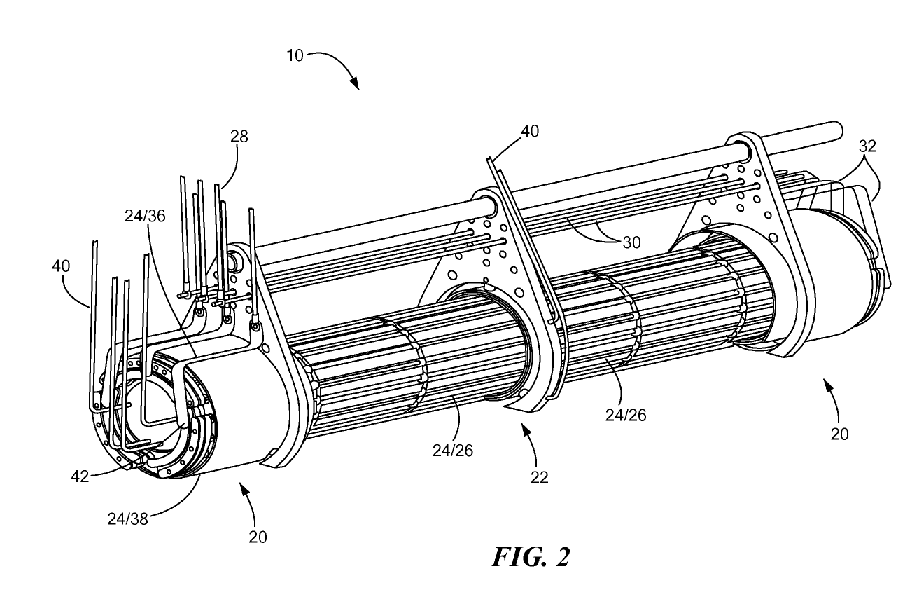

To mitigate vapor condensation within its interior, the deposition source 10 has a plurality of resistive heating elements 24 along its body 12, and a one-piece heat shield 19 (also referred to as an “insulation layer 19,” discussed below) about the heating elements 24 to retain the heat within the deposition source 10. By removing the outside insulation 19 in the central distribution region 22, FIG. 2 schematically shows one embodiment of some of the heating elements 24 in the body 12. As shown, the heating elements 24 include a plurality of generally parallel rods 26 extending longitudinally across the body 12. These rods 26 preferably are formed from material that is highly conductive at high temperatures, and also can withstand high temperatures. One material that should provide satisfactory results includes graphite.

High currents transmitted through the rods 26 generates the required high temperatures (e.g., 1250-1450 degrees C.). For example, an external power source may generate a high current, which is transmitted to the graphite rods 26 through a set of power connectors 28 near one end of the source 10. A plurality of return conductors 30 complete the circuits to generate these high currents. In a manner similar to the graphite rods 26, the return conductors 30 have a relatively low resistance at high temperatures and thus, are capable of conducting very high currents. Since they are outside of the deposition source 10, however, they do not have to withstand the same high temperatures as those in the area of the graphite rods 26. Among other things, molybdenum return rods 30 should provide satisfactory results. Corresponding flexible conductors 32 connect the return conductors 30 to the graphite rods 26. To ensure flexible strain relief during thermal expansion, these flexible conductors 32 may be made from niobium or other similar material.

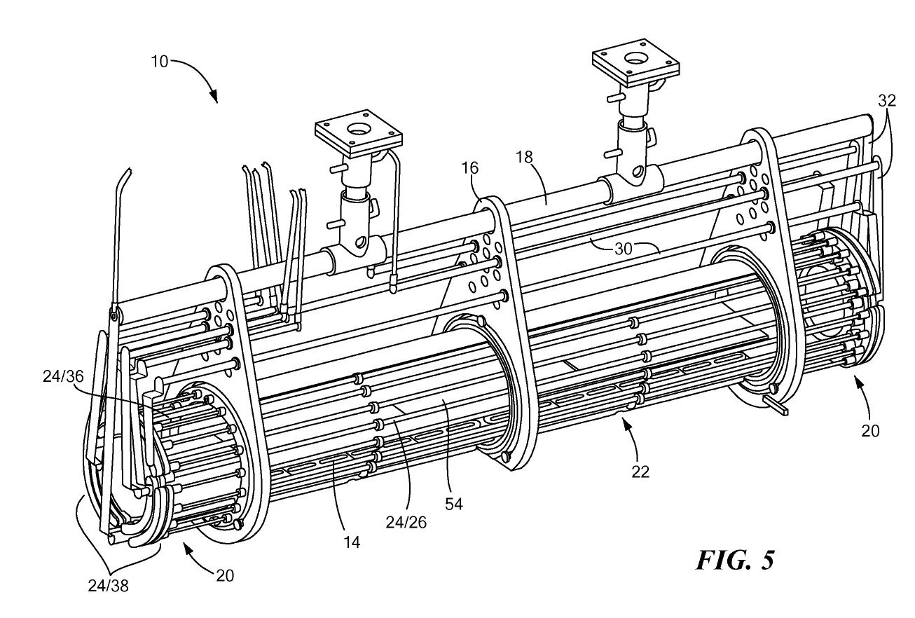

During use, each end region 20 is pre-loaded with a material to be vaporized and subsequently deposited onto one or more surfaces of the substrate. The material preferably is loaded in a solid state into a crucible 34 near or at the end region 20. The form factor of the material preferably minimizes air in its crucible 34 (the crucible 34 is shown in FIGS. 5-8, discussed below) while maximizing its volume in its crucible 34. In illustrative embodiments, the material is in the form of a plurality of rectangular bars that closely fit together, thus leaving very little open air within its crucible 34.

Those skilled in the art understand that limited temperature control in this end region 20 can adversely impact the thin layer deposited on the underlying substrate. The heating system within this region (i.e., at each end region 20) itself thus preferably has three independent zones surrounding the crucible 34. Specifically, the body 12 contains a first resistively heated element generally above the crucible 34 (“top heating element 36,” shown schematically), and two additional resistively heated elements beginning at the sides of the crucible 34 and extending toward its bottom (“bottom heating elements 38”, shown schematically). Each of these heating elements 36 and 38 are independently controlled.

To minimize heat loss, this region of the body 12 also has the above noted heat shield/insulation material 19 surrounding these heating elements 36 and 38 (discussed below). As noted, the heat shield 19 can be one piece. Alternatively, multiple pieces can form a single heat shield 19. During use, it is anticipated that only the top heating element 36 will be necessary in many applications. The bottom heating elements 38 nevertheless provide additional flexibility to ensure that the material is properly heated.

The end region 20 also has a plurality of temperature sensors 40 that assist in controlling its temperature profile within its interior. Among other things, the temperature sensors 40 can include conventional thermocouples. The temperature sensors 40 can direct an electrical signal to end heater control logic that monitors the temperature. As a result, if the temperature is too low, then the control logic can apply more heat to the end region 20. Conversely, if the temperature is too high, then the control logic can apply less heat to the end region 20.

Despite these safeguards, a temperature variation of a few degrees within this region can have a significant impact on the performance of the entire deposition source 10. The heating elements 36 and 38 in this region may be too coarse to provide such fine control. Moreover, the end region 20 of this and many other types of deposition sources should be sealed to maintain the temperature profile at appropriate levels.

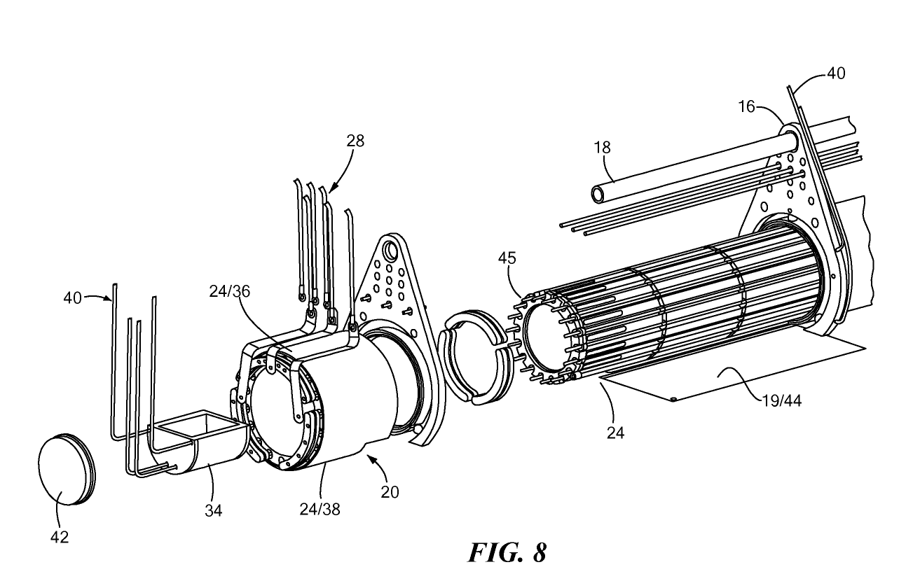

Accordingly, illustrative embodiments provide a source end heater (hereinafter “end heater 42”) that insulates its respective end region 20 (and consequently the entire deposition source 10), while at the same time delivering finely tuned heating to the material being vaporized. As shown in FIG. 2 (and FIG. 8, discussed below), this end heater 42 has a relatively small, compact form factor secured within the end of the deposition source 10. The end heater 42 preferably has an outer shape that corresponds with that of the end region 20—they fit in registry within the portion of the body 12. The end heater 42 in this embodiment thus has a generally circular outer shape. In contrast, deposition sources having a different shape can have end heaters 42 with correspondingly different shapes.

As known by those in the art, the temperature differential between the interior of the deposition source 10 and the vacuum chamber (i.e., exterior to the deposition source 10) can be significant. For example, the internal temperature of the deposition source 10 can be about 1250-1450 degrees C., while the temperature within the vacuum chamber can be about 500-600 degrees C. Accordingly, as noted above, the deposition source 10 therefore has a significant heat shield/insulation layer 19 to maintain its internal thermal environment.

The insulation layer 19 and heating elements 24 thus cooperate to maintain the heat profile within the deposition source 10 at a pre-specified range (e.g., fifty degrees above the condensation temperature of the material in the crucibles 34). FIG. 3 schematically shows additional details of the insulation layer 19. This insulation layer 19 illustratively extends across substantially the entire body 12 of the deposition source 10, and encompasses the graphite heating rods 26.

In illustrative embodiments, the insulation layer 19 fits closely around an internal liner 45 formed from a material that can withstand high temperatures. Among other things, the insulation layer 19 may include a plurality of molybdenum sheets near the liner 45, and a plurality of stainless steel sheets with ceramic blankets therebetween. Of course, the insulation layer 19 may be formed from different materials and thus, the specific materials are discussed for exemplary purposes only.

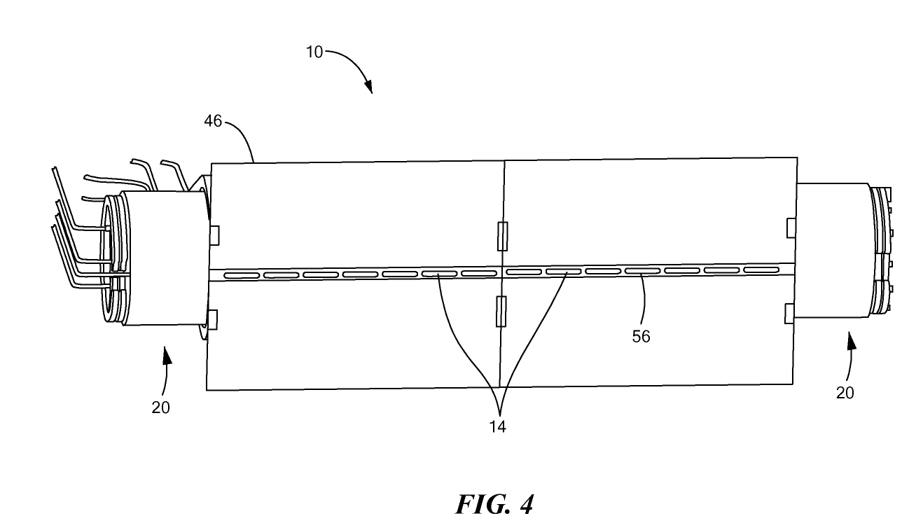

As shown in FIGS. 3 and 4, the insulation layer 19 has a cylindrical portion 44, and an integral, substantially planar, bottom portion 46. The cylindrical portion 44 has a shape that corresponds to that of the internal liner 45, while the bottom portion 46 insulates the underlying substrate from heat generated by the deposition source 10. In accordance with illustrative embodiments of the invention, the cylindrical portion 44 preferably is a single-piece element with no corners or edges (i.e., other than possibly the interface of the bottom and cylindrical portions 46 and 44). In addition, the cylindrical portion 12 illustratively has a total outside surface area that is larger than that of any non-cylindrical portion of the body 12.

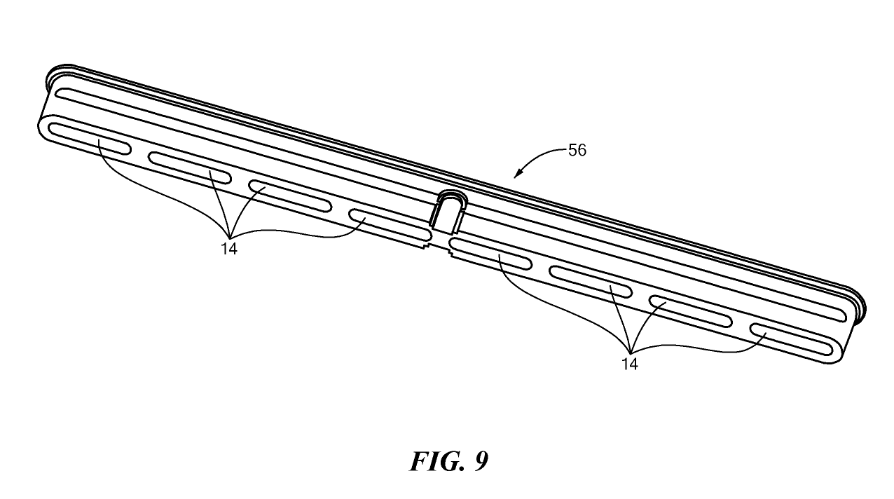

The interior liner 45 may be formed from a number of materials, such as graphite. In illustrative embodiments, conventional processes form the liner 45 by etching a bore through a solid cylindrically shaped graphite element. The internal surface of the graphite liner 45 may be coated with a layer of inert pyrolytic boron nitride or silicon carbide. Conventional processes also may form exit orifices 14 through the liner 45, or areas to mount removable arrays of exit orifices 14 (i.e., inserts 56, discussed below with respect to FIG. 9) to the liner 45.

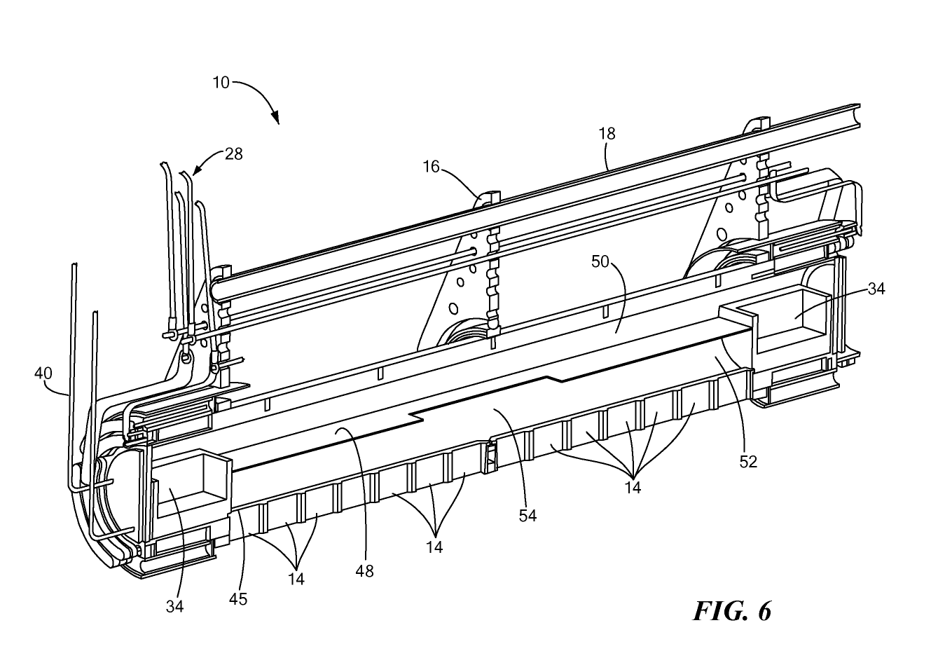

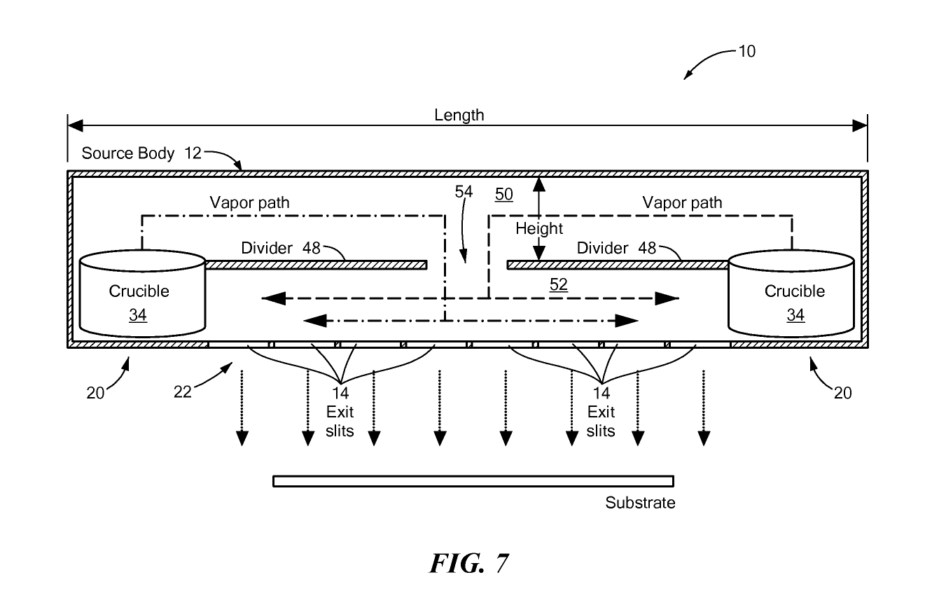

FIG. 5 schematically shows the deposition source 10 with both the liner 45 and the insulation layer 19 removed. This view, along with corresponding FIGS. 6 and 7, show details of the interior of the deposition source 10. As shown in these figures, the interior chamber of the body 12 contains 1) first and second crucibles 34 at each of the end regions 20 (e.g., proximate to the ends of the body 12), and 2) a divider member 48 (hereinafter “divider 48”) that divides the central distribution region 22 into a transport channel 50 for receiving vapor from the crucibles 34, and a distribution channel 52 for substantially evenly distributing the vapor received from the transport channel 50. As shown, the transport channel 50, distribution channel 52, and exit orifices 14 are vertically aligned in a stacked configuration to provide a compact design. In other words, from the perspective of the view shown in FIG. 7, the three components 50, 52, and 14 are spaced vertically and share at least one common plane that is orthogonal to the longitudinal axis of the body 12.

FIG. 7 schematically shows the vapor path within the body 12 during use. To that end, the divider 48 has a set of one or more divider apertures 54 that fluidly connect the transport and distribution channels 50 and 52, thus effectively fluidly connecting the crucibles 34 with the exit orifices 14. During use, vapor from the crucibles 34 travel along the transport channel 50 toward the divider aperture 54 and into the distribution channel 52. As discussed in greater detail below, the vapor substantially evenly fills the distribution channel 52, and exits through the exit orifices 14, which are between the crucibles 34 in this embodiment, to substantially uniformly coat the underlying substrate.

The geometry and configuration of the distribution source 10 ensures that the source 10 deposits a uniform, generally flat coating onto the underlying substrate. Accordingly, in accordance with illustrative embodiments, the set of divider apertures 54 are substantially symmetrically positioned, relative to the length of the distribution channel 52, within the interior chamber of the body 12. Specifically, the divider apertures 54 are uniformly positioned about the longitudinal center of the distribution channel 52. In other words, like one embodiment of the body 12 discussed above, the set of apertures are capable of division by a plane oriented parallel to the middle plate 16 (orthogonal to the longitudinal axis) at the longitudinal center of the distribution channel 52 into corresponding, equal sets of apertures. To that end, the divider apertures 54 may be configured to be substantial mirror images about the longitudinal center of the distribution channel 52.

For example, the embodiments shown in FIGS. 5-7 have a single divider aperture 54 that is substantially in the middle of the interior chamber. Accordingly, if the distribution channel 52 were cut in half, each resulting half would have mirror image aperture(s) 54. More specifically, if the distribution channel 54 of FIG. 7 were cut in half, then the left half of the distribution channel 54 would have about half the area of the aperture 54, while the right half of the aperture 54 would have the other half of the area of the aperture 54. These two halved aperture areas may have mirror image shapes and/or geometries, or other shapes and geometries. In illustrative embodiments, however, regardless of their actual shapes and geometries, both aperture halves are configured to pass substantially the same amount of vapor flux under similar conditions.

Some embodiments have more than one aperture 54 that are symmetrically positioned relative to the distribution channel 52 to function in the same manner as discussed above with regard to FIG. 7. Their spacing and orientation can be empirically and/or mathematically determined to produce the desired results. Other embodiments may position different numbers of apertures 54 on either side of the distribution channel center (e.g., one aperture 54 on one side and a plurality of apertures 54 on the other side). In those and other cases discussed herein, the aperture(s) 54 preferably are configured so that they generate a vapor flux that substantially evenly distributes that vapor, within the distribution channel 52, relative to its longitudinal center—i.e., during use, the vapor concentration and flow/flux ideally should be substantially the mirror image about the longitudinal center of the distribution channel 52. This should more evenly distribute the vapor to the exit orifices 14.

The vapor thus enters the distribution channel 52 at or around its center and travels toward the exit orifices 14 at both ends in a generally uniform manner. Accordingly, even if the two crucibles 34 produce vapor at different rates or volumes, the vapor distribution within the distribution channel 52 still should be substantially uniform/constant. The vapor distribution should be contrasted with the actual pressure within the distribution channel 52, which is not necessarily constant (although it may be). Moreover, some embodiments may have only one crucible 34, three crucibles 34, or other numbers of crucibles 34 and yet, still deliver to substantially uniform vapor distribution.

Pressure differentials within the distribution source 10 and on the outside of the distribution source 10 cause the vapor to travel from the crucibles 34, and ultimately through the exit orifices 14. Specifically, the pressure in the transport channel 50 is higher than that in the distribution channel 52, causing flow from the transport channel 50 into the distribution channel 52. In a corresponding manner, the pressure within the distribution channel 52 is higher than that on the outside of the deposition source 10, causing vapor to travel through the exit orifices 14 and onto the substrate.

In accordance with illustrative embodiments, as noted above, the pressure distribution within the distribution channel 52 is substantially uniform/constant. This consequently ensures that the pressure distribution on the interior side of the exit orifices 14 also remains substantially constant. Accordingly, as pressures within the distribution channel 52 change, the vapor flux through each exit orifices 14 changes in a predefined, known manner. More specifically, the pressure distribution between the exits is defined as the pressure differential between the exit orifices 14 (referred to as “delta P”) divided by the average exit orifice pressure. As noted, this quotient should remain substantially constant.

An example of a distribution channel 52 with only two exit orifices 14 using simple numbers can illustrate this phenomenon. If the pressure of a first exit orifice 14 is 1.0, and that of a second exit orifice 14 is 1.2 (ignoring units), then their pressure differential is 0.2 (i.e., 1.2 less 1.0). Their average pressure is 1.1 and thus, the pressure distribution is:

0.2/1.1=0.1818 (Equation 1)

Complying with this relationship, if the pressure at each of the exit orifices 14, including these two orifices 14, increases by a factor of 10, then the new pressure of the first exit orifice 14 is 10.0, and that of the second exit orifice 14 is 12.0. Their pressure differential now is 2.0 and their average pressure now is 11.0. Their pressure differential remains the same:

2.0/11−0.1818 (Equation 2)

To cause this phenomenon, the volume of the distribution channel 52 preferably is sized and configured to have a much smaller flow resistance than that of the sum of the exit orifices 14. Thus, the distribution channel volume is much larger than the volume of the sum of all of the exit orifices 14. The inventors have determined that a distribution channel volume that is about five times or more larger than that of the sum of the exit orifices 14 should produce satisfactory results. This result is expected to be true regardless of the pressure distribution within the transport channel 50, which can have a volume that is less than that of the distribution channel 52.

The divider 48 also protects against so-called “spitting” of the material in its liquid form from the crucibles 34. Specifically, solid or semi-solid droplets of the material undesirably may shoot from the crucible 34 holding the material being vaporized. These droplets can clog one or more of the exit orifices 14, which can cause an uneven material distribution on the substrate. In addition, these droplets can cause a “bump” or other undesirably imperfection if deposited on the substrate.

Accordingly, the divider 48 is configured and positioned within the base interior to substantially mitigate these undesirable droplets from clogging the exit orifices 14 and/or striking the substrate. The distribution channel 52 thus may be considered to directly shield the majority of the exit orifices 14 (or all of the exit orifices 14) from these droplets. To those ends, the divider 48 causes the transport channel 50 to have an elongated shape—long and shallow. In illustrative embodiments, the length is at least three or four times its height. Thus, a droplet ejected from the crucible 34 most likely will strike a wall of the transport channel 50 rather than passing through the divider aperture 54 and into the distribution channel 52. To ensure a large distribution channel volume and a long but shallow transport channel 50, the divider 48 illustratively is positioned closer to the top of the base than it is to the exit orifices 14 (note that the figures are not drawn to scale). The transport channel volume thus may be less than that of the distribution channel 52.

FIG. 8 schematically shows an exploded view of one end region 20 of the deposition source 10 and its components. Among other things, this view shows one of the crucibles 34, the end heater 42, some of the thermocouples 40, a portion of the shield/insulation layer 19, power connectors 28, the end heater 42, heating elements 24/36 at that region, etc. . . . This figure is included simply as another way to show the components of illustrative embodiments of the deposition source 10.

As noted above, the pressure distribution across the exit orifices 14 preferably is substantially constant. Despite this, without some intervention, the vapor flux through the exit orifices 14 near the center of the body 12 may be greater than that of the exit orifices 14 nearer to the ends of the source 10 (i.e., nearer the end regions 20). To ensure a smooth, substantially even vapor flux through the orifices 14, illustrative embodiments vary the geometry of the different exit orifices 14 as a function of their location along the length of the body 12. Accordingly, the shape, size, volume, and cross-sectional areas, among other things, of the orifices 14 of this embodiment are selected as a function of their location on the source 10 and the material being vaporized. Any one or more of those geometrical features can be altered to control the vapor flux through the exit orifices 14.

For example, in some embodiments, the pressure nearer the center of the distribution channel 52 may be somewhat greater than that near the end regions 20. In a corresponding manner, without modifying the geometry of the exit orifices 14, the vapor flux through the more centrally located exit orifices 14 may be greater than the flux through the less centrally located orifices 14. The orifices 14 nearer the end regions 20 thus may be configured to provide less fluid resistance to the vapor, thus producing more vapor flux. Ideally, this different geometry should produce a substantially uniform vapor flux through the exit orifices 14. To that end, the interior orifices 14 have a smaller average cross-sectional area or volume than the orifices 14 near the end region 20. Empirical processes based upon the material being vaporized and the orifice location may assist in determining their appropriate geometries.

The exit orifices 14 may be shaped, either all the same way or in a different way, to produce a prescribed vapor pattern. For example, as shown in FIG. 9, the exit orifices 14 may have an elongated shape to deposit material on a smaller, more focused region on the substrate. As a few other examples, the exit orifices 14 may have a circular, elliptical, or irregular shape. The exit orifices 14 toward the end may have a specialized shape to control the vapor pattern in a manner that minimizes vapor from beyond the edge of the substrate, while maximizing the vapor at the substrate edges.

Rather than vary the geometry of the exit orifices 14, however, some embodiments simply have all identically configured exit orifices 14—they all have the same geometry. In either case, the exit orifices 14 may be arranged as a one or two dimensional array. In other embodiments, the exit orifices 14 are arranged in a seemingly random pattern, a regular pattern, or some other pattern.

Some embodiments have changeable/modifiable exit orifices 14. This provides more flexibility in the vapor deposition patterns and enables a given deposition source 10 to be used (at different times) with different materials. To that end, FIG. 9 schematically shows an insert 56 having a plurality of exit orifices 14, while FIG. 3 schematically shows two inserts 56 in a bottom view of the deposition source 10. These exit orifices 14 may be arranged to have similar geometries, or different geometries as discussed above.

To secure the insert 56 to its bottom/lower region, the body 12 has a corresponding female channel for receiving the insert 56, and a conventional securing mechanism. Alternatively, the insert 56 may not be secured within the female channel—it is simply secured about the exterior of the channel. The insert 56 may be substantially permanently secured to the body 12, or removably connected.

Illustrative embodiments using inserts 56 provide flexibility to the operator of the deposition source 10. For example, if, during use, the currently connected inserts 56 are breaking down, clogging, or otherwise producing less than optimal results, an operator may replace them with new, identical inserts 56. In a similar manner, if a different vapor pattern is required, an operator may replace the currently connected inserts 56 with new inserts 56, consequently providing a different vapor pattern.

Illustrative embodiments therefore should deliver more controllable vapor deposition layers on an underlying substrate. The symmetrical body 12 and apertures 54, as well as configuration of the distribution channel 52, reduce material spitting and facilitate a more controlled vapor flux exit from the source 10.

Although the above discussion discloses various exemplary embodiments of the invention, it should be apparent that those skilled in the art can make various modifications that will achieve some of the advantages of the invention without departing from the true scope of the invention.

What is claimed is:

1. A vapor deposition source for vaporizing a material, the vapor deposition source comprising:
a body forming an interior chamber having at least two ends;
first and second crucibles in the interior chamber, the first crucible being positioned proximate to the first chamber end, the second crucible being positioned proximate to the second chamber end;
a divider that divides the interior chamber into a transport channel and a distribution channel; and
a plurality of exit orifices formed in the body adjacent to the distribution channel,
the divider having a set of divider apertures between the transport channel and the distribution channel, the set of divider apertures being generally symmetrically positioned relative to the distribution channel within the interior chamber.

2. The vapor deposition source as defined by claim 1 wherein the set of divider apertures includes no more than one divider aperture.

3. The vapor deposition source as defined by claim 1 wherein the transport channel volume is less than the distribution channel volume.

4. The vapor deposition source as defined by claim 1 wherein the set of divider apertures includes a plurality of divider apertures.

5. The vapor deposition source as defined by claim 1 wherein the transport channel has a length and a height, the length being at least 3 times greater than the height.

6. The vapor deposition source as defined by claim 1 wherein the transport channel is vertically aligned with the distribution channel.

7. The vapor deposition source as defined by claim 1 wherein the first and second crucibles are generally symmetrically positioned relative to the set of divider apertures.

8. The vapor deposition source as defined by claim 1 wherein the first and second crucibles are longitudinally spaced apart relative to the body, the first and second crucibles being fluidly connected to the transport channel.

9. The vapor deposition source as defined by claim 1 wherein the distribution channel is elongated with a length dimension having a center, the set of apertures being positioned along the length dimension of the distribution channel, the set of apertures being generally symmetrically positioned about the center of the distribution channel.

10. A vapor deposition source for vaporizing a material, the vapor deposition source comprising:
a body forming an interior chamber;
first and second crucibles in the interior chamber;
a divider that divides the interior chamber into a transport channel and a distribution channel; and
a plurality of exit orifices formed in the body adjacent to the distribution channel and between the first and second crucibles,
the divider having a set of divider apertures between the transport channel and the distribution channel, the set of divider apertures being generally symmetrically positioned relative to the distribution channel within the interior chamber.

11. The vapor deposition source as defined by claim 10 wherein the first and second crucibles are longitudinally spaced apart relative to the body, the first and second crucibles being fluidly connected to the transport channel.

12. The vapor deposition source as defined by claim 10 wherein the body is longitudinally-symmetrical shaped.

13. The vapor deposition source as defined by claim 10 wherein the transport channel fluidly communicates the first and second crucibles.

14. A vapor deposition source system for vaporizing a material, the vapor deposition source comprising:
a body forming an interior chamber;
at least one crucible in the interior chamber;
a divider that divides the interior chamber into a transport channel and a distribution channel; and
a plurality of exit orifices formed in the body adjacent to the distribution channel,
the divider having a set of divider apertures between the transport channel and the distribution channel, the set of divider apertures being generally symmetrically positioned relative to the distribution channel within the interior chamber,
the exit orifices being in a stacked configuration with the transport channel.

15. The vapor deposition source system as defined by claim 14 wherein the exit orifices, transport channel, and distribution channel are in a stacked configuration.

16. The vapor deposition source system as defined by claim 14 wherein the body is substantially longitudinally-symmetrical shaped.

17. The vapor deposition source system as defined by claim 14 wherein each of the plurality of exit orifices has an orifice volume, the distribution channel having a volume that is at least five times the sum of the orifice volumes of all of the exit orifices.

18. The vapor deposition source system as defined by claim 14 further comprising a vacuum chamber, at least one crucible being within the vacuum chamber.

19. A vapor deposition source for vaporizing a material, the vapor deposition source comprising:
a body forming an interior chamber;
at plurality of crucibles in the interior chamber, the plurality of crucibles being spaced apart;
a divider that divides the interior chamber into a transport channel and a distribution channel, the transport channel fluidly communicating the plurality of crucibles; and
a plurality of exit orifices formed in the body adjacent to the distribution channel and between the first and second crucibles,
the divider having a set of divider apertures between the transport channel and the distribution channel, the set of divider apertures being generally symmetrically positioned relative to the distribution channel within the interior chamber.

20. The vapor deposition source as defined by claim 19 wherein the plurality of crucibles are adjacent.

21. The vapor deposition source as defined by claim 20 wherein the plurality of crucibles are in contact.

22. The vapor deposition source as defined by claim 19 wherein the interior chamber has an elongated shape with two ends, each of the two ends having at least one of the plurality of crucibles.

23. A vapor deposition source for vaporizing a material, the vapor deposition source comprising:
a body forming an interior chamber;
at least one crucible in the interior chamber for supporting and providing material vapor; and
a plurality of exit orifices formed in the body to expose the interior chamber to the exterior of the body, the body having a generally elongated shape with a pair of end regions, the plurality of exit orifices at least being positioned generally along the length between the end regions, the plurality of exit orifices having different geometries,
the plurality of exit orifices including an edge orifice and interior orifice, the edge orifice being positioned between one of the end regions and the interior orifice, the edge orifice having a geometry configured to permit substantially the same material flux through it as the material flux through the interior orifice when the pressure proximate to the edge orifice is lower than the pressure proximate to the interior orifice.

24. The vapor deposition source as defined by claim 23 wherein the edge orifice is configured to permit more material flux through it than the material flux through the interior orifice when the edge orifice and interior orifice are subjected to substantially identical pressures.

25. The vapor deposition source as defined by claim 23 wherein the edge orifice has a greater cross-sectional area than the interior orifice.

26. The vapor deposition source as defined by claim 23 comprising a removable member removably connected with the body, the removable member including at least one of the plurality of exit orifices.

27. The vapor deposition source as defined by claim 26 wherein the removable member comprises an array of exit orifices.

28. The vapor deposition source as defined by claim 23 further comprising a plurality of removable members, each removable member having a plurality of exit orifices, the removable members having dissimilar exit orifices from one another.

29. The vapor deposition source as defined by claim 23 wherein the body comprises an opening and a removable member secured within the opening, the removable member including at least one of the plurality of exit orifices.

30. A method of forming a film on a substrate, the method comprising:
producing a vapor of material within a vapor deposition source, the vapor deposition source having a distribution channel with a plurality of exit orifices, the plurality of exit orifices having different geometries;
moving a substrate adjacent the exit orifices of the vapor deposition source;
applying a pressure to the vapor within the distribution channel to eject vapor from the exit orifices; and
the substrate receiving the vapor ejected from the exit orifices, the vapor forming a coating of material on the substrate, the coating having a substantially uniform thickness across the substrate.

31. The method as defined by claim 30 wherein the plurality of exit orifices comprises an edge orifice and an interior orifice, the edge orifice having a greater cross-sectional area than the cross-sectional of the interior orifice.

32. A vapor deposition source for vaporizing a material, the vapor deposition source comprising:
a body forming an interior chamber, the interior chamber having a divider forming a distribution channel and a transport channel;
at least one crucible in the interior chamber for vaporizing material;
a plurality of exit orifices formed in the body to expose the interior chamber to the exterior of the body,
the body having a cylindrical portion with a circumference of greater than about 180 degrees.

33. The vapor deposition source as defined by claim 32 wherein the body has a cross-sectional shape that is either circular or elliptical.

34. The vapor deposition source as defined by claim 32 wherein the body has a total outside surface area, the cylindrical portion comprising more than half of the total outside surface area of the body.

35. The vapor deposition source as defined by claim 32 wherein the exit orifices interrupt the outside surface of the body.

36. The vapor deposition source as defined by claim 32 wherein the body includes a high temperature material layer, and a one-piece insulation layer radially outwardly of the high temperature material layer.

37. The vapor deposition source as defined by claim 36 wherein the high temperature material layer comprises fine grain high density graphite.

38. The vapor deposition source as defined by claim 32 wherein the cylindrically shaped portion has no seams or edges along its exterior circumference.

39. A vapor deposition source for vaporizing a material, the vapor deposition source comprising:
an elongated body forming an interior chamber, the interior chamber forming a distribution channel having a channel volume;
at least one crucible in the interior chamber for vaporizing material; and
a plurality of exit orifices formed in the body to expose the distribution channel to the exterior of the body, each of the plurality of exit orifices having an orifice volume, the channel volume being at least five times the sum of the orifice volumes of all of the exit orifices.

40. The vapor deposition source as defined by claim 39 wherein the distribution channel shields a majority of the exit orifices from each of the at least one crucibles.

41. The vapor deposition source as defined by claim 40 further comprising a transport channel for directing vapor into the distribution channel, the transport channel being elongated and sized to substantially eliminate material spitting.

42. The vapor deposition source as defined by claim 40 further comprising a transport channel for directing vapor into the distribution channel, the transport channel being fluidly connected to the distribution channel at a channel interface, the transport channel being spaced from the exit orifices and having a length and a height that substantially eliminate material spitting.

43. The vapor deposition source as defined by claim 39 further comprising a transport channel for directing vapor into the distribution channel, the transport channel having a length and an average height, the length being at least 3 times greater than the average height.

44. The vapor deposition source as defined by claim 39 wherein, when in use, the distribution channel has a substantially constant vapor pressure distribution.

45. The vapor deposition source as defined by claim 39 wherein, when in use, the pressure distribution across the exit orifices is substantially constant.
